(19) United States
(12) Patent Application Publication
(10) Pub. No.: US 2025/0211199 A1
(43) Pub. Date: Jun. 26, 2025

(54) PIEZOELECTRIC-ON-INSULATOR (POI) SUBSTRATE AND METHOD FOR PRODUCING A PIEZOELECTRIC-ON-INSULATOR (POI) SUBSTRATE

(71) Applicant: Soitec, BERNIN (FR)

(72) Inventors: Raphaël Caulmilone, BERNIN (FR); Frédéric Allibert, BERNIN (FR); Isabelle Bertrand, BERNIN (FR)

(21) Appl. No.: 18/852,209

(22) PCT Filed: Mar. 30, 2023
(86) PCT No.: PCT/EP2023/058282

§ 371 Date: Sep. 27, 2024

(30) Foreign Application Priority Data
Mar. 30, 2022 (FR) FR2202900

(51) Int. Cl. H03H 9/02; H03H 3/08

(52) U.S. Cl. CPC H03H 9/02952; H03H 3/08; H03H 9/02559; H03H 9/02574

(57) ABSTRACT

A piezoelectric-on-insulator (POI) substrate comprises: a carrier substrate, in particular, a substrate based on silicon; a piezoelectric layer, in particular, a layer of lithium tantalate or of lithium niobate; a dielectric layer, in particular, a layer of silicon oxide, sandwiched between the piezoelectric layer and the substrate; a trapping structure sandwiched between the dielectric layer and the carrier substrate. The trapping structure comprises at least two trapping layers, which layers are separated each time by a dielectric intermediate layer. A method is used for producing such a piezoelectric-on-insulator substrate.

### CROSS-REFERENCE TO RELATED APPLICATIONS

This application is a national phase entry under 35 U.S.C. § 371 of International Patent Application PCT/EP2023/058282, filed Mar. 30, 2023, designating the United States of America and published as International Patent Publication WO 2023/187050 A1 on Oct. 5, 2023, which claims the benefit under Article 8 of the Patent Cooperation Treaty of French Patent Application Serial No. FR2202900, filed Mar. 30, 2022.

### TECHNICAL FIELD

The present disclosure relates to a piezoelectric-on-insulator (POI) substrate comprising, in this order, a support substrate, a trapping structure, a dielectric layer and a piezoelectric layer, and also to a process for the manufacture of such a POI substrate.

### BACKGROUND

Such substrates are known in the state of the art. Devices, such as sensors or filters, are produced in and/or on the piezoelectric layer.

### BRIEF SUMMARY

The trapping structure makes it possible to reduce losses related to side effects at the interface between the support substrate and the dielectric layer. This is because the trapping layer, which is inserted between the support substrate and the dielectric layer, serves to decrease the density of free carriers and to prevent variations in the Fermi level. This results in a higher and constant resistivity in the support substrate, which makes possible a reduction in side effects, such as the attenuation of the signal, the generation of harmonic signals or direct coupling.

However, it is observed that, during heat treatments in the context of or subsequent to the manufacture of the POI substrates, metal elements of the piezoelectric layer, such as lithium, can diffuse through the dielectric layer and the trapping structure as far as the interface with the support substrate. The accumulation of these metal elements reduces the performance qualities of the trapping structure and the suppression of side effects is thus negatively affected.

The object of the present disclosure is thus to reduce the harmful effect of the diffusion of the metal elements through the structure of the POI substrate.

The object of the present disclosure is achieved by a piezoelectric-on-insulator (POI) substrate comprising: a support substrate, in particular, a silicon-based substrate, a piezoelectric layer, in particular, a layer of lithium tantalate (LTO) or of lithium niobate (LNO), a dielectric layer, in particular, a silicon oxide layer, sandwiched between the piezoelectric layer and the support substrate, a trapping structure sandwiched between the dielectric layer and the support substrate, characterized in that the trapping structure comprises at least two trapping layers, the trapping layers being separated from one another by a dielectric intermediate layer. The separation of the trapping structure into at least two trapping layers with a dielectric layer between two trapping layers makes it possible to segregate a part of the contamination by the metal elements at the interfaces between the trapping layers, the intermediate layer thus reducing the cumulative level of the metal elements at the interface between the trapping structure and the support structure. Thus, the side effect can be effectively reduced. The support substrate can preferably have a resistivity of greater than or equal to 500 Ω·cm.

According to one embodiment, the trapping layers of the POI substrate can be based on polycrystalline or amorphous or porous silicon or based on silicon carbide (SiC). Such layers effectively reduce the side effects.

According to one embodiment, the dielectric intermediate layer of the POI substrate can be a layer of silicon oxide, in particular, a layer of native silicon oxide or a layer deposited by chemical vapor deposition (CVD) or a layer obtained by thermal oxidation. Silicon oxides are easy to produce and at the same time it is possible to observe an accumulation of the diffused metal elements at the interfaces of the intermediate layers of the trapping structure.

According to one embodiment, the dielectric intermediate layer(s) of the POI substrate can have a thickness equal to or less than 5 nm, in particular, equal to or less than 1 nm. Even layers of such low thicknesses show an effect on the reduction in the side effects.

According to one embodiment, at least two of the at least two trapping layers can have one or more physical properties, in particular, a grain size, which are different. Thus, it becomes possible to further improve the suppression of the side effects.

According to one embodiment, each trapping layer of the POI substrate can have the same thickness. According to one alternative, at least one trapping layer of the POI substrate can have a different thickness from the other trapping layer(s). This makes it possible to optimize the properties of the POI substrate.

According to one embodiment, the trapping structure of the POI substrate can have a thickness equal to or less than 5 μm, preferably equal to or less than 2 μm. Thus, even with thinner trapping structures than in the state of the art, it is possible to obtain a satisfactory reduction in the side effect.

The object of the present disclosure is also achieved by the process for the manufacture of a piezoelectric-on-insulator (POI) substrate as described above and comprising the stages of: providing a support substrate, in particular, a silicon-based substrate, providing a substrate comprising a piezoelectric layer, in particular, a substrate comprising lithium tantalate (LTO) or lithium niobate (LNO), forming a trapping structure above the support substrate, forming a dielectric layer, in particular, a silicon oxide layer, above the substrate comprising a piezoelectric layer and/or above the trapping structure, assembling the substrate comprising a piezoelectric layer with the support substrate such that the dielectric layer and the trapping structure are sandwiched between the piezoelectric layer and the support substrate, characterized in that the stage of forming the trapping structure comprises forming a first trapping layer, forming a dielectric intermediate layer on the first trapping layer and forming a second trapping layer on the dielectric intermediate layer. With this process, a substrate can be obtained, which makes it possible to effectively reduce the negative effect of the diffusion of metal elements toward the support substrate.

According to one embodiment, the process for the manufacture of a piezoelectric substrate can additionally comprise a stage of: forming a weakened zone inside the piezoelectric layer, and carrying out fracturing along the weakened zone in order to separate a part of the piezoelectric layer from the remainder of the substrate comprising the piezoelectric layer after the assembling stage in order to transfer the part of the piezoelectric layer onto the support substrate. This process makes it possible to industrially manufacture the POI substrates according to the present disclosure.

### BRIEF DESCRIPTION OF THE DRAWINGS

The present disclosure and its advantages will be explained in more detail subsequently by way of advantageous embodiments, given as example, and with the support of the following figures, in which the reference numbers identify characteristics of the present disclosure.

FIG. 1 diagrammatically represents a piezoelectric-on-insulator (POI) substrate according to a first embodiment of the present disclosure.

FIG. 2 diagrammatically represents a piezoelectric-on-insulator (POI) substrate according to a second embodiment of the present disclosure.

FIG. 3 diagrammatically represents a piezoelectric-on-insulator (POI) substrate according to a third embodiment of the present disclosure.

FIG. 4 diagrammatically represents a process for the manufacture of a piezoelectric-on-insulator (POI) substrate according to a fourth embodiment of the present disclosure.

### DETAILED DESCRIPTION

The embodiments described constitute only possible configurations and it should be remembered that the individual characteristics as described above can be provided independently of one another or can be omitted entirely during the implementation of the present disclosure.

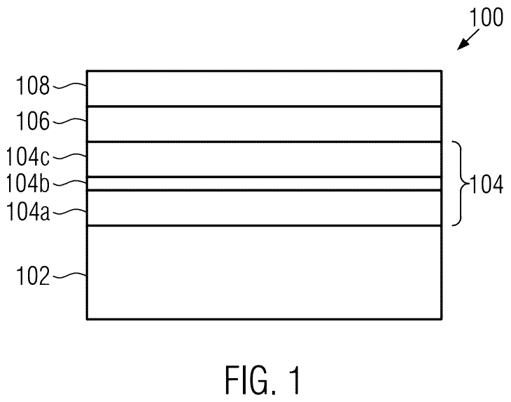

FIG. 1 diagrammatically represents a piezoelectric-on-insulator (POI) substrate 100 according to the first embodiment of the present disclosure.

The piezoelectric-on-insulator substrate 100 comprises a support substrate 102. In this first embodiment, the support substrate 102 is a silicon-based substrate, in particular, a single-crystal silicon wafer. The support substrate preferably has a resistivity of greater than or equal to 500 Ω·cm.

A trapping structure 104 is arranged above the support substrate 102. The trapping structure 104 can be in direct contact with the support substrate 102. The trapping structure 104 has a thickness equal to or less than 5 μm, preferably equal to or less than 2 μm.

According to the first embodiment, the trapping structure 104 comprises three layers: a first trapping layer 104a, a dielectric intermediate layer 104b and a second trapping layer 104c.

The trapping layers 104a, 104c are based on polycrystalline or amorphous or porous silicon or based on silicon carbide (SiC). Preferably, they are layers deposited by low-pressure chemical vapor deposition (LPCVD). In this embodiment, the two trapping layers 104a, 104c have the same thickness.

The dielectric intermediate layer 104b can be a layer of silicon oxide, preferably a layer of native silicon oxide. According to alternative forms, the dielectric intermediate layer can also be formed by chemical vapor deposition (CVD) or by thermal oxidation. The dielectric intermediate layer 104b preferably has a lower thickness than the trapping layers 104a, 104c, in particular, a thickness that is equal to or less than 5 nm, especially equal to or less than 1 nm.

A dielectric layer 106 is arranged above, in particular, directly on, the trapping structure 104. The dielectric layer 106 is preferably a layer based on silicon oxide. The dielectric layer 106 preferably has a thickness between 100 nm and 1 μm, in particular, between 200 nm and 700 nm. The dielectric layer 106 can be formed by CVD deposition or any other appropriate deposition process.

A piezoelectric layer 108 is arranged above, in particular, directly on, the dielectric layer 106. It is preferably a layer of lithium tantalate (LTO) or of lithium niobate (LNO). The piezoelectric layer 108 typically has a thickness of between 200 nm and 1 μm.

According to an alternative form, the two trapping layers 104a and 104c can have one or more physical properties, such as the grain size, which are different.

The separation of the trapping structure 104 into at least two trapping layers 104a, 104c with a dielectric intermediate layer 104b between the two trapping layers 104a, 104c makes it possible to segregate a part of the contamination by the metal elements at the interfaces between the trapping layers 104a, 104c and the dielectric intermediate layer 104b, thus reducing the concentration of the metal elements at the interface between the trapping structure 104 and the support substrate 102. Thus, the reduction in the suppression of the side effects is compensated for.

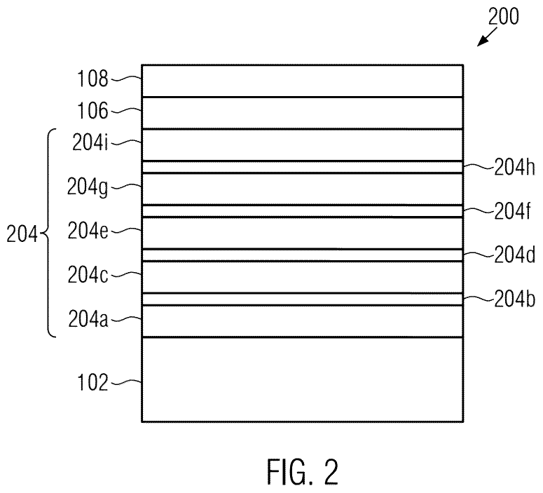

FIG. 2 diagrammatically represents a piezoelectric-on-insulator (POI) substrate 200 according to a second embodiment of the present disclosure.

The piezoelectric-on-insulator substrate 200 comprises the support substrate 102, the dielectric layer 106 and the piezoelectric layer 108 of the first embodiment. A fresh description of these layers and of their properties is omitted and reference is made to their description above in connection with the first embodiment.

The only difference being the first and the second embodiments lies in the use of another trapping structure 204.

In the second embodiment, the trapping structure 204 comprises, in total, five trapping layers 204a, 204c, 204e, 204g and 204i. An intermediate dielectric layer 204b, 204d, 204f and 204h is each time inserted between two trapping layers.

The trapping layers 204a, 204c, 204e, 204g and 204i are produced in the same way as the trapping layers 104a and 104c of the first embodiment and they have the same physical properties as the layers 104a, 104c. They have, in particular, all the same thicknesses, especially all a thickness of 0.2 μm or less.

Likewise, the intermediate dielectric layers 204b, 204d, 204f and 204h are produced in the same way as the dielectric intermediate layer 104b of the first embodiment and they have the same physical properties as this layer 104b. They have, in particular, all the same thicknesses, especially all a thickness of a few tens of nanometers (a few angstroms), in particular, of one nanometer or less (10 angstroms or less).

By multiplying the interfaces in the trapping structure 204, the concentration of the metal elements, in particular, of lithium, at the interface between the first trapping layer 204a and the support substrate 102 can be further reduced, because metal elements are trapped at each interface. Thus, the amount of metal elements that arrive at the interface with the support substrate 102 is lower than in a structure with fewer interfaces.

According to alternative forms, more or fewer trapping layers and dielectric intermediate layers can be provided in the trapping structure, depending on the concentration level of metal elements regarded as acceptable for a given application.

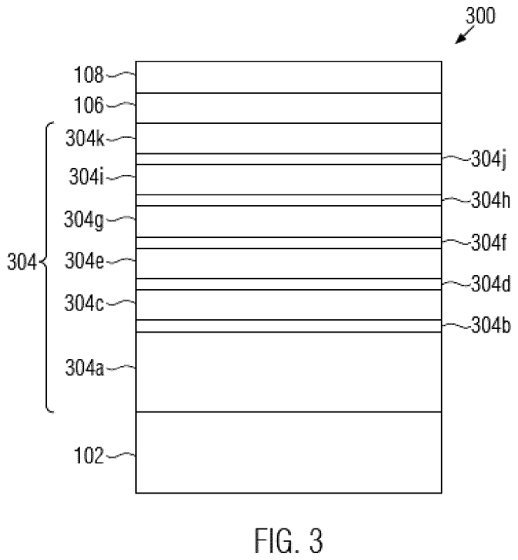

FIG. 3 diagrammatically represents a piezoelectric-on-insulator (POI) substrate 300 according to a third embodiment of the present disclosure.

The piezoelectric-on-insulator substrate 300 comprises the support substrate 102, the dielectric layer 106 and the piezoelectric layer 108 of the first embodiment. These layers and their properties will not be described again but reference is made to their description in the first embodiment.

The only difference between the first and the third embodiments lies in the use of another trapping structure 304.

In this embodiment, the trapping structure 304 comprises several trapping layers 304a, 304c, 304e, 304g, 304i and 304k, which, as in the second embodiment, are separated by dielectric intermediate layers 304b, 304d, 304f, 304h and 304j.

The dielectric intermediate layers 304b, 304d, 304f, 304h and 304j are produced as in the first or second embodiment and have the same thicknesses, for example, of a few tens of nanometers (a few angstroms), in particular, of one nanometer or less (of 10 angstroms or less).

On the other hand, while the several thin trapping layers 304c, 304e, 304g, 304i and 304k all have the same thicknesses, for example, 0.1 μm or less, the trapping layer 304a is thicker, in particular, with a thickness of 0.5 μm or more.

By multiplying the interfaces in the trapping structure 304, the concentration of the metal elements, in particular, of lithium, at the interface between the first trapping layer 304a and the support substrate 102 can be reduced, as in the second embodiment. The trapping layer 304a at the interface with the support substrate 102 is thicker and thus retains its trapping properties.

According to alternative forms, more or fewer trapping layers and dielectric intermediate layers can be provided in the trapping structure, depending on the cumulative level of metal elements regarded as acceptable for a given application.

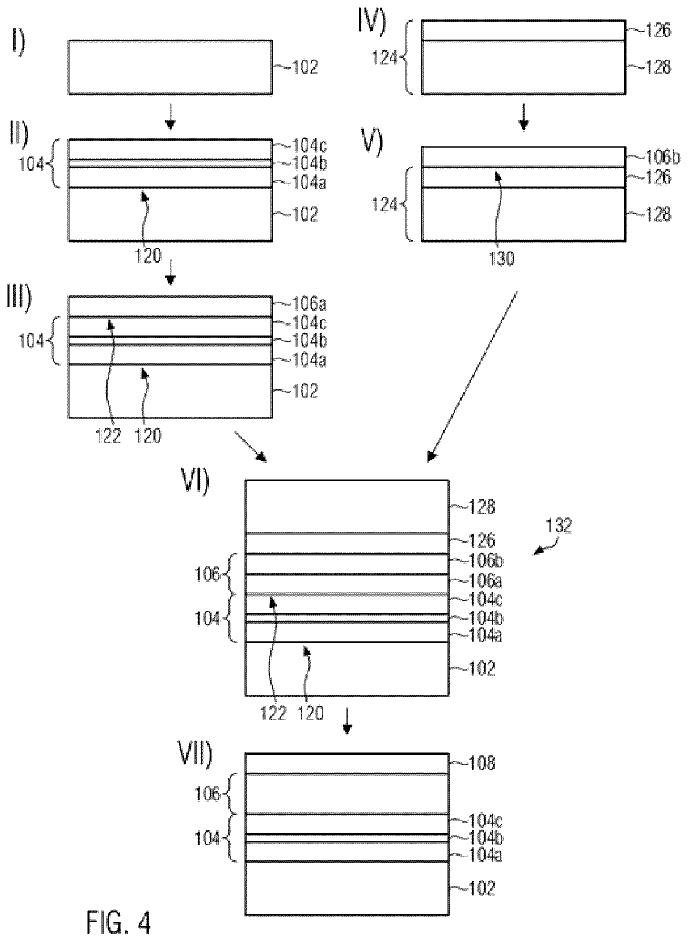

FIG. 4 diagrammatically represents a process for the manufacture of a piezoelectric-on-insulator (POI) substrate according to the fourth embodiment of the present disclosure in order to obtain a POI substrate 100 according to the first embodiment as described above in connection with FIG. 1. The reference numbers already used in the description of the POI substrate 100 of FIG. 1 are reused for the description of the process.

The process for the manufacture of a piezoelectric-on-insulator (POI) substrate 100 begins with stage I) of providing a support substrate 102, in particular, a silicon-based substrate, especially a single-crystal silicon wafer.

According to this fourth embodiment of the present disclosure, stage II) provides the formation of the trapping structure 104 on a free surface 120 of the support substrate 102.

The formation of the trapping structure 104 begins with the formation of first trapping layer 104a produced by low-pressure chemical vapor deposition (LPCVD). According to alternative forms, the formation can be carried out by a thermal growth technique or by physical vapor deposition (PVD).

The trapping layer 104a formed on the support substrate 102 is a layer based on polycrystalline, amorphous or porous silicon or based on silicon carbide. The thickness of the trapping layer 104a is equal to or less than 2.5 μm, in particular, equal to or less than 1 μm.

Subsequently, a dielectric intermediate layer 104b is formed on the first trapping layer 104a. The dielectric intermediate layer 104b can be a layer of silicon oxide, preferably a layer of native silicon oxide. According to one of the alternative forms, the dielectric intermediate layer is formed by chemical vapor deposition (CVD) or by thermal oxidation. The dielectric intermediate layer 104b preferably has a lower thickness than the first trapping layer 104a, in particular, a thickness that is less than 5 nm, especially less than 1 nm.

In order to complete the formation of the trapping structure 104, a second trapping layer 104c is formed on the dielectric intermediate layer 104b in the same way as the first trapping layer 104a and, in particular, with the same thickness.

According to an alternative form, the two trapping layers 104a and 104c can be formed with one or more physical properties, such as the grain size, which are different. According to another alternative form, the two trapping layers 104a and 104c can be based on different materials, among those named above. For example, the trapping layer 104a can be made of porous silicon and the trapping layer 104a made of polycrystalline silicon.

During stage III), a dielectric layer 106a is formed on the free surface 122 of the second trapping layer 104c. The dielectric layer 106a is preferably a silicon oxide layer formed by chemical vapor deposition (CVD) or by physical vapor deposition (PVD). According to an alternative form, the dielectric layer 106a is formed by oxidation of polycrystalline silicon.

The dielectric layer 106a preferably has a thickness equal to or less than 1 μm, in particular, equal to or less than 700 nm.

A heat treatment can be carried out after the deposition of the dielectric layer 106a in order to densify it.

During stage IV), a substrate 124 comprising a piezoelectric layer 126, in particular, a substrate 124 comprising lithium tantalate (LTO) or lithium niobate (LNO), is provided. The piezoelectric layer 126 is, in this embodiment, arranged above a base substrate 128. In an alternative, the piezoelectric layer 126 is a bulk layer and forms the substrate 124 in its entirety.

During stage V), a second dielectric layer 106b, in particular, a silicon oxide layer, is produced on the free surface 130 of the piezoelectric layer 126. This layer is produced in the same way as the dielectric layer 106a formed during stage III). The thickness is chosen such that the sum of the thicknesses of the two dielectric layers 106a and 106b is between 100 nm and 1 μm, in particular, between 200 nm and 700 nm.

According to an alternative form, one or more stages of surface treatment of the free surface 130 of the substrate 124 comprising a piezoelectric layer 126 can be carried out before the formation of the dielectric layer 106b. For example, a surface activation treatment, such as a plasma treatment and/or an ozone-based treatment, can be carried out.

During stage VI), the substrate 124 obtained after stage V) is assembled with the support substrate 102 obtained in the assembling stage III) in order to form a support substrate—substrate comprising a piezoelectric layer assembly 132.

The assembling is carried out so that the dielectric layers 106a and 106b are brought into direct contact. The assembling is preferably carried out by molecular adhesion.

Once the two substrates are assembled, a stage VII) of thinning the assembly 132 is carried out in order to obtain the POI substrate 100 with a thinner piezoelectric layer 108, as illustrated in FIG. 1.

For example, the thinning stage can be carried out by milling or by a stage of formation of a weakened zone in the piezoelectric layer 126 before the assembling stage VI), so as to delimit the piezoelectric layer 108 to be transferred onto the support substrate 102, and fracturing. This stage of formation of a weakened zone is carried out by an implantation of atomic or ionic entities in the piezoelectric layer 126. The atomic or ionic implantation can be carried out in such a way that the weakened zone is situated inside the piezoelectric layer 126 and delimits a piezoelectric layer 108 to be transferred from the remainder of the piezoelectric layer 126. Subsequently, a stage of fracturing the assembly 132 by supplying thermal and/or mechanical energy at the weakened zone of the piezoelectric layer 126 is subsequently carried out in order to obtain the piezoelectric-on-insulator (POI) substrate 100.

According to alternative forms, the bonding between the support substrate 102 and the substrate 124 can also be carried out between the trapping structure 104 and the dielectric layer 106b, that is to say without carrying out stage III), or between the dielectric layer 106a and the piezoelectric layer 126.

Before producing one or more of the abovementioned layers, one or more stages of cleaning, brushing or polishing the surface directly below can be carried out in order to remove the presence of particles and dust.

The process can also be applied in order to obtain the POI substrates 200 and 300 of the second and third embodiments of the present disclosure described in connection with FIG. 2 and FIG. 3, respectively.

1. A piezoelectric-on-insulator (POI) substrate, comprising:
a substrate;
a piezoelectric layer;
a dielectric layer;
a trapping structure sandwiched between the dielectric layer and the support substrate, the trapping structure comprising at least two trapping layers, the at least two trapping layers being separated from one another by a dielectric intermediate layer, at least two of the at least two trapping layers having at least one different physical property.

2. The POI substrate of claim 1, wherein each of the at least two trapping layers is based on polycrystalline and/or amorphous and/or porous silicon and/or based on silicon carbide.

3. The POI substrate of claim 1, wherein the dielectric intermediate layer is a layer of silicon oxide.

4. The POI substrate of claim 1, wherein the dielectric intermediate layer has a thickness equal to or less than 5 nm.

5. The POI substrate of claim 1, wherein each trapping layer of the at least two trapping layers has the same thickness.

6. The POI substrate of claim 1, wherein at least two of the at least two trapping layers have different thicknesses.

7. The POI substrate of claim 1, wherein the trapping structure has a thickness equal to or less than 5 μm.

8. A method of manufacturing a POI substrate according to claim 1, the method comprising:
providing a support substrate;
providing a substrate comprising a piezoelectric layer;
forming a trapping structure on the support substrate, the forming of the trapping structure including forming a first trapping layer, forming a dielectric intermediate layer on the first trapping layer, and forming a second trapping layer on the dielectric intermediate layer, the first trapping layer and the second trapping layer having at least one different physical property;
forming a dielectric layer on the substrate comprising the piezoelectric layer and/or on the trapping structure; and
assembling the substrate comprising the piezoelectric layer with the support substrate such that the dielectric layer and the trapping structure are sandwiched between the piezoelectric layer and the support, substrate.

9. The method of claim 8, further comprising:
forming a weakened zone inside the piezoelectric layer; and
fracturing the piezoelectric layer along the weakened zone to separate a part of the piezoelectric layer from a remainder of the substrate comprising the piezoelectric layer after the assembling to transfer the part of the piezoelectric layer onto the support substrate.

10. The POI substrate of claim 1, wherein the support substrate comprises a silicon-based substrate.

11. The POI substrate of claim 1, wherein the piezoelectric layer comprises a layer of lithium tantalate (LTO) or a layer of lithium niobate (LNO).

12. The POI substrate of claim 1, wherein the at least one different physical property comprises an average grain size.

13. The POI substrate of claim 3, wherein the dielectric intermediate layer is a layer of native silicon oxide.

14. The POI substrate of claim 3, wherein the dielectric intermediate layer is a layer deposited by chemical vapour deposition (CVD) or a layer obtained by thermal oxidation.

15. The POI substrate of claim 4, wherein the dielectric intermediate layer has a thickness equal to or less than 1 nm.

16. The POI substrate of claim 6, wherein at least one trapping layer of the at least two trapping layers is disposed directly on the support substrate and has a thickness greater than a thickness of another trapping layer of the at least two trapping layers.

17. The POI substrate of claim 7, wherein the trapping structure has a thickness equal to or less than 2 μm.

18. The POI substrate of claim 2, wherein the dielectric intermediate layer is a layer of silicon oxide.

19. The POI substrate of claim 18, wherein the dielectric intermediate layer has a thickness equal to or less than 5 nm.

20. The POI substrate of claim 19, wherein at least one trapping layer of the at least two trapping layers is disposed directly on the support substrate and has a thickness greater than a thickness of another trapping layer of the at least two trapping layers.
